(19) United States
(12) Patent Application Publication
(10) Pub. No.: US 2010/0185913 A1
(43) Pub. Date: Jul. 22, 2010

(54) METHOD FOR DECODING LDPC CODE AND THE CIRCUIT THEREOF

(75) Inventors: YEN CHIN LIAO, JHUBEI CITY (TW); CHUN HSIEN WEN, JHUBEI CITY (TW); YUNG SZU TU, JHUBEI CITY (TW); JIUNN TSAIR CHEN, JHUBEI CITY (TW)

Correspondence Address: HAMRE, SCHUMANN, MUELLER & LARSON, P.C., P.O. BOX 2902, MINNEAPOLIS, MN, 55402-0902, US

(73) Assignee: RALINK TECHNOLOGY CORPORATION, JHUBEI CITY (TW)

(21) Appl. No.: 12/499,760

(22) Filed: Jul. 8, 2009

(30) Foreign Application Priority Data
Jan. 16, 2009 (TW) 098101474

(51) Int. Cl. H03M 13/05; G06F 11/10; G06F 12/12

(52) U.S. Cl. 714/752; 714/E11.032; 711/118; 711/E12.07

(57) ABSTRACT

A method for decoding LDPC code comprises the steps of: marking non-zero sub-matrices of a parity-check matrix of an LDPC code as 1 and zero sub-matrices of the parity-check matrix as 0 to form a simplified matrix; rearranging the sequence of rows of the simplified matrix according to the dependency between these rows; and updating the LDPC code in accordance with the sequence of the rows.

### BACKGROUND OF THE INVENTION

1. Field of the Invention

The present invention relates to low density parity check (LDPC) code, and more particularly, to a method for decoding LDPC code and the circuit thereof.

2. Description of the Related Art

LDPC code is one type of error correction code that is used in many communication systems. LDPC code is the first among many error correction codes to successfully approach the Shannon limit defined in information theory. Although the LDPC code initially had no practical use due to its computation complexity, the required computations thereof are no longer difficult with the progress of integrated circuit technology. Due to superb error correction capability, the wireless communication device complying with IEEE 802.11n standard utilizes LDPC code as its error correction code.

Belief propagation algorithm is currently the main LDPC code decoding algorithm. Belief propagation algorithm corrects errors by repeatedly updating the parity check matrix of an LDPC code. FIG. 1 shows a conventional LDPC code decoding circuit. The decoding circuit 100 comprises a memory 110, a first cyclic-shift module 120, an updating unit 130 and a second cyclic-shift module 140. The memory 110 stores the entries of the parity check matrix of an LDPC code. The first cyclic-shift module 120 is coupled to the memory 110 for the cyclic-shift operation in the decoding process. The updating unit 130 is coupled to the first cyclic-shift module 120 for updating the entries of the parity check matrix, including updating check nodes and variable nodes. The second cyclic-shift module 140 is coupled to the updating unit 130 for the inverse operation of the first cyclic-shift module 120 to recover the order of the entries in the parity check matrix.

The process of decoding LDPC code comprises four steps: (a) initializing and calculating the intrinsic information of each coding bit; (b) updating the check nodes; (c) updating the variable nodes; and (d) computing hard decision. When initializing, the memory 110 receives an input signal with soft information, which implicitly contains the probability of each coding bit being 0 or 1. During the decoding process, the input of the memory 110 switches to the output of the second cyclic-shift module 140, and steps (b) to (d) are repeated until a valid codeword is found or the number of repetitions exceeds a threshold value.

In flood-type belief propagation algorithm, the check nodes and the variable nodes are updated sequentially. However, in shuffled-type belief propagation algorithm, the check nodes and the variable nodes are updated in an interleaving manner. In other words, when a check node is updated, the linked variable node is updated accordingly, and vice versa. Theoretically, shuffled-type belief propagation algorithm updates more frequently and converges much faster. In practice, however, when a check node is updated, the update of the check node is usually not finished when the following variable node is to be updated, and vice versa. At this point, the update of the variable node could be held until the update of the check node is finished. This pause slows down the decoding process. On the other hand, the update of the variable node could continue before the update of the check node is finished by using the value of the check node before update. However, such approach reduces the likelihood of successful decoding.

In addition, when the decoding process operates at a higher clock rate, the updating steps are often proceeding in a parallel manner such that the wide bandwidth and high power consumption required by the memory increases the complexity of the circuit design.

Therefore, there is a need to design a method for decoding LDPC code and the circuit thereof to reduce the access rate of the memory, which can provide improved decoding success rate, reduced power consumption, and simpler circuit design.

### SUMMARY OF THE INVENTION

The embodiments of the present invention disclose a method and circuit for decoding LDPC code, wherein according to the disclosed method and circuit the data to be decoded is reordered in order to reduce the access rate of memory.

The method for decoding LDPC code according to one embodiment of the present invention comprises the steps of: marking non-zero sub matrixes as 1 and zero sub matrixes as 0 in the parity check matrix of an LDPC code to generate a simplified matrix; reordering the rows of the simplified matrix according to the correlation of these rows; and updating decoding data according to the sequence of these rows.

The circuit for decoding LDPC code according to another embodiment of the present invention comprises a memory, a first cyclic-shift module, an updating unit and a second cyclic-shift module. The operation of the first cyclic-shift module is the reverse of that of the second cyclic-shift module, and the first cyclic-shift module can switch to receive either the output data of the memory or the output data of the updating unit. The memory is configured to store decoding data of an LPDC code, and can switch to receive either an input data to be decoded or the output data of the second cyclic-shift module. The updating unit is configured to update the output data of the first cyclic-shift module. The second cyclic-shift module is configured to cyclic shift the output data of the updating unit.

The circuit for decoding LDPC code according to yet another embodiment of the present invention comprises a memory, a first cyclic-shift module, a second cyclic-shift module, an updating unit, a third cyclic-shift module, a fourth cyclic-shift module and a cache memory. The memory is configured to store decoding data of an LPDC code, and can switch to receive either an input data to be decoded or the output data of the fourth cyclic-shift module. The operation of the first cyclic-shift module is the reverse of that of the second cyclic-shift module, and the first cyclic-shift module can switch to receive either the output data of the updating unit or the output data of the cache memory. The third cyclic-shift module is configured to cyclic shift the output data of the memory. The updating unit is configured to update the output data of the first cyclic-shift module and the third cyclic-shift module. The second cyclic-shift module is configured to cyclic shift the output data of the updating unit. The fourth cyclic-shift module is configured to cyclic shift the output data of the updating unit. The cache memory is configured to receive and store either the output data of the memory or the output data of the updating unit.

### BRIEF DESCRIPTION OF THE DRAWINGS

The objectives and advantages of the present invention will become apparent upon reading the following description and upon referring to the accompanying drawings of which:

FIG. 1 shows a conventional LDPC code decoding circuit;

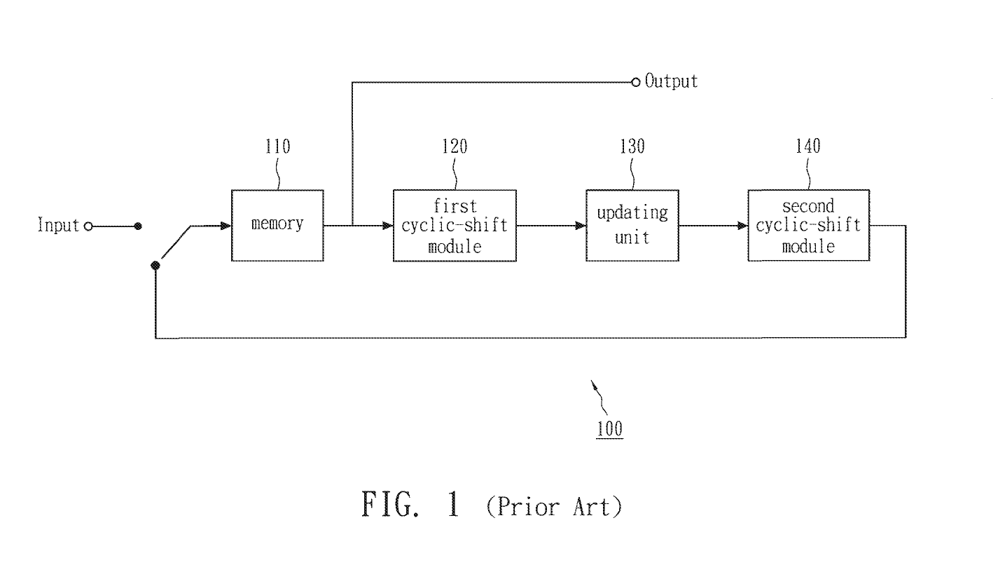

FIG. 2 shows the flow chart of the method for decoding LDPC code according to an embodiment of the present invention;

FIG. 3 shows a circuit for decoding LDPC code according to an embodiment of the present invention;

FIG. 4 shows a parity check matrix according to an embodiment of the present invention;

FIG. 5 shows a simplified matrix according to an embodiment of the present invention;

FIG. 6 shows a reorder result according to the method for decoding LDPC code according to an embodiment of the present invention;

FIG. 7 shows a circuit for decoding LDPC code according to another embodiment of the present invention; and

FIG. 8 shows a circuit for decoding LDPC code according to yet another embodiment of the present invention.

### DETAILED DESCRIPTION OF THE INVENTION

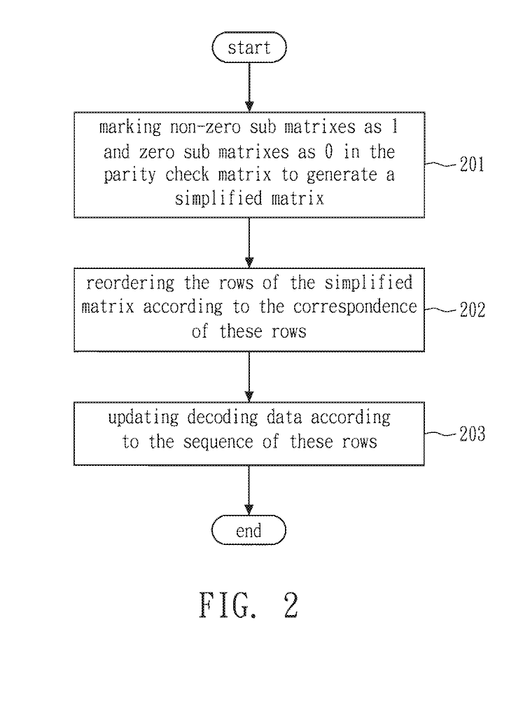

FIG. 2 shows the flow chart of the method for decoding LDPC code according to an embodiment of the present invention. In step 201, non-zero sub matrixes in the parity check matrix are marked as 1 and zero sub matrixes in the parity check matrix are marked as 0 to generate a simplified matrix, and step 202 is executed. In step 202, the rows of the simplified matrix are reordered according to the correlation of these rows, and step 203 is executed. In step 203, decoding data is updated according to the sequence of these rows.

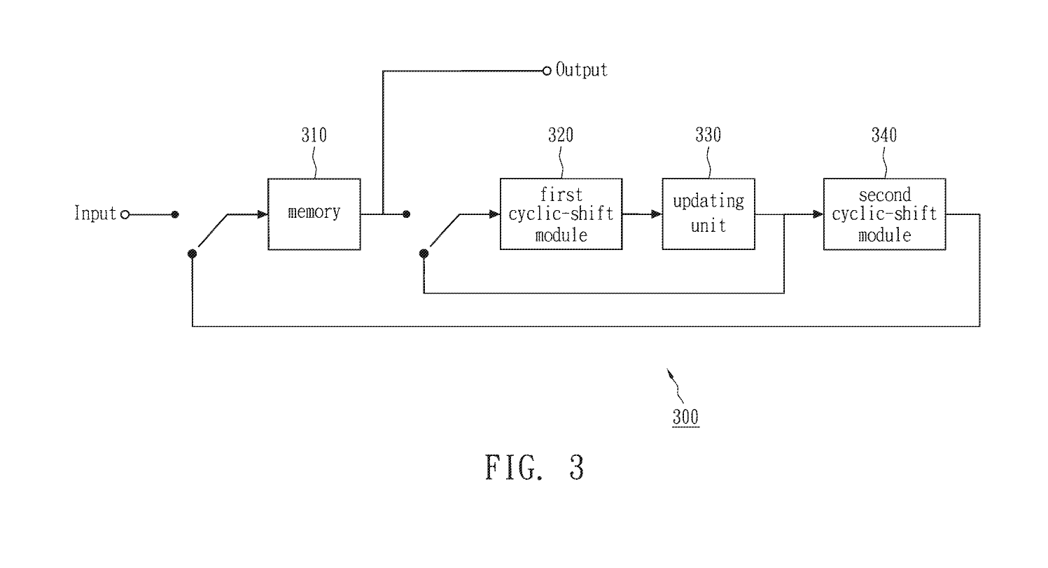

FIG. 3 shows a circuit for decoding LDPC code according to an embodiment of the present invention. The decoding circuit 300 comprises a memory 310, a first cyclic-shift module 320, an updating unit 330 and a second cyclic-shift module 340. The memory 310 is configured to store the decoding data of an LPDC code, and can switch to receive either an input data to be decoded with soft information or the output data of the second cyclic-shift module 340, and its output terminal is coupled to a hard decision output terminal. The first cyclic-shift module 320 can switch to receive either the output data of the memory 310 or the output data of the updating unit 330, and is configured to cyclic shift its input data. The updating unit 330 is configured to update the output data of the first cyclic-shift module 320, i.e., to update the check nodes and variable nodes. The second cyclic-shift module 340 is configured to cyclic shift the output data of the updating unit 330. In some embodiments, the cyclic-shift modules can be implemented by barrel shifters.

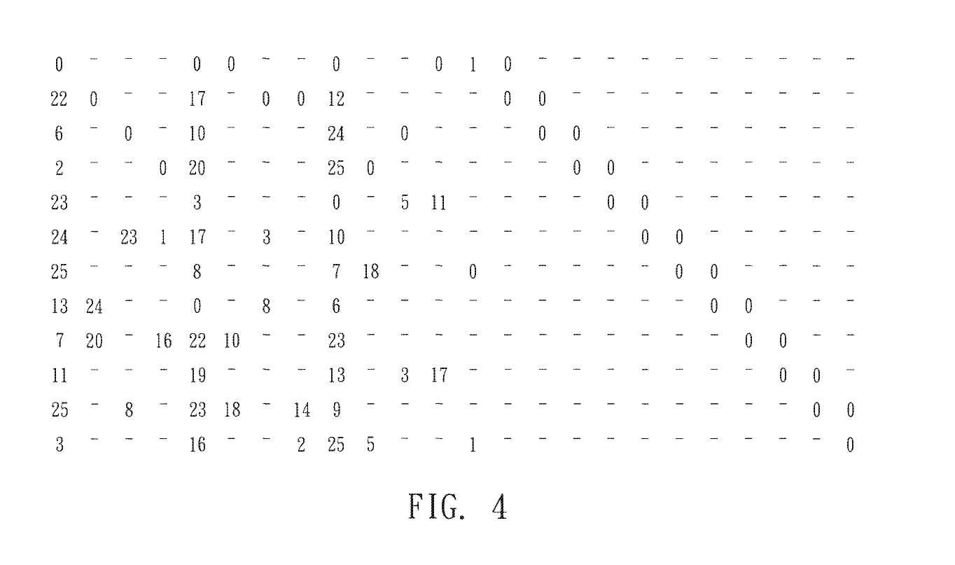

FIG. 4 shows the parity check matrix of an LDPC code utilized in a wireless communication device complying with IEEE 802.11n standard. Each entry of the parity check matrix represents a sub matrix of 27 columns and 27 rows, wherein each ‘−’ represents a zero matrix, and each numeral represents a matrix generated by cyclic shifting the number of columns from an identity matrix. As shown in FIG. 4, due to the structural properties of the parity check matrix, each check node can be updated simultaneously. In other words, the 27 check nodes can be updated simultaneously during the decoding process, and therefore the corresponding 27 decoding data fields can be considered as the same decoding block and stored in the same memory address.

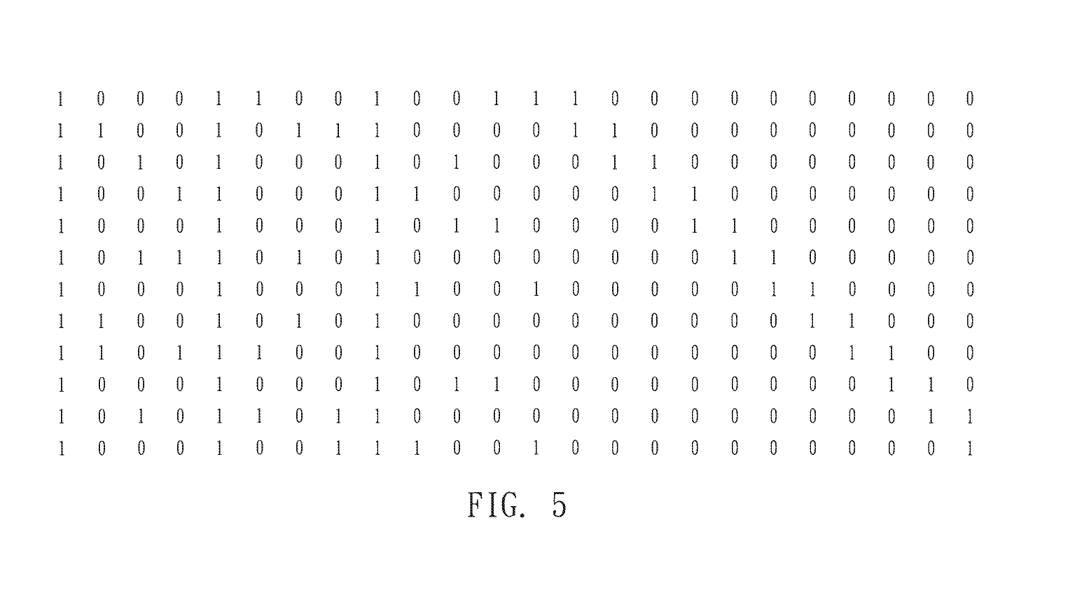

The following description depicts applying the decoding method shown in FIG. 2 to decode the wireless communication signals shown in FIG. 4. In step 201, the entries represented by ‘−’ are marked as 0s, and the other entries are marked as is, as shown in FIG. 5. In step 202, the rows of the simplified matrix shown in FIG. 5 are reordered according to the correlation of these rows. In the present embodiment, all of the rows of the simplified matrix are treated as binary numbers, and are reordered numerically. If the leftmost column is considered as the highest order, then the sequence of these rows is the 9^{th} row, the 2^{nd} row, the 8^{th} row, the 6^{th} row, the 11^{th} row, the 3^{rd} row, the 4^{th} row, the 1^{st} row, the 12^{th} row, the 7^{th} row, the 5^{th} row and the 10^{th} row. However, in other embodiments, these rows can be reordered according to the results of XOR computations or by Gray code encoding method. In step 203, the decoding data are updated according to the sequence of these rows.

According to the method and circuit of the embodiments of the present invention, since all of the rows of the simplified matrix are reordered according to their correlation, each row has a higher correlation with its upper row and lower row. In other words, each row has more entries at same columns with its upper row and lower row compared with any other rows, wherein the decoding data of the sub matrixes corresponding to the entries at same columns are stored in the same address. Therefore, when the decoding data is updated according to the sequence of these rows, there are many successive update operations to the decoding data stored in the same address. These update operations can be directly executed, i.e. the first cyclic-shift module 320 receives the output data of the updating unit 330 directly to execute the cyclic shift operation and then outputs the results to the updating unit 330 for the next update without storing the decoding data to the memory 310. In this way, the access rate of the memory 310 is reduced.

In some embodiments, the updating unit 330 updates the decoding data corresponding to these rows sequentially. To reduce the read-after-write hazards generated by updating, the read and write operations of the entries of these rows are also reordered in these embodiments: i.e., the updating order of the decoding data is determined according to the correlation between the row corresponding to these decoding data and its upper and lower rows. In some embodiments, if the entry corresponding to the decoding data to be updated also has upper and lower entries with decoding data to be updated, then these decoding data are updated lastly and are stored firstly after being updated, wherein the read sequence of the decoding data is opposite to the write sequence of this decoding data.

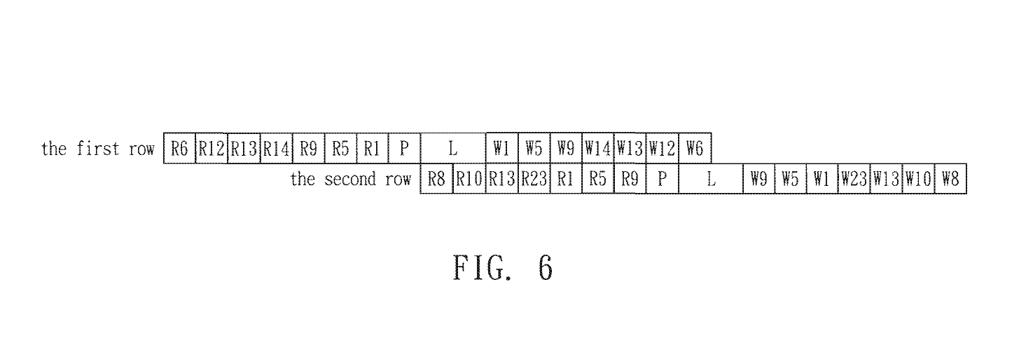

FIG. 6 shows the reordered result of the read and write operation of the entries of the first row of the simplified matrix shown in FIG. 5 in these embodiments, wherein RS represents the read operation of the decoding data corresponding to the S^{th} entry, P represents the update operation, L represents pipeline delay and WS' represents the write operation of the decoding data corresponding to the S^{th} entry. According to the above reordering method, the entries of the 1^{st} row, the 4^{th} row and the 12^{th} row are checked to obtain the observation that the 1^{st} column, the 5^{th} column and the 9^{th} column all have an entry corresponding to the decoding data to be updated in each of these three rows. As shown in FIG. 6, when updating the first row, the read operation of the decoding data corresponding to the 1^{st}, the 5^{th} and the 9^{th} entries are listed last, and the write operation of the decoding data corresponding to the 1^{st}, the 5^{th} and the 9^{th} entries are listed first. When updating the twelfth row, the read operation of the decoding data corresponding to the 1^{st}, the 5^{th} and the 9^{th} entries are also listed last, and the write operation of the decoding data corresponding to the 1^{st}, the 5^{th} and the 9^{th} entries are also listed first. As shown in FIG. 6, the write operation of the decoding data corresponding to the 1^{st}, the 5^{th} and the 9^{th} entries of the first row are prior to that of the 1^{st}, the 5^{th} and the 9^{th} entries of the twelfth row, and therefore no read-after-write hazard occurs. However, for those read and write operations which may still cause read-after-write hazards, a cache memory may be utilized to store the decoding data to be written to avoid such read-after-write hazards.

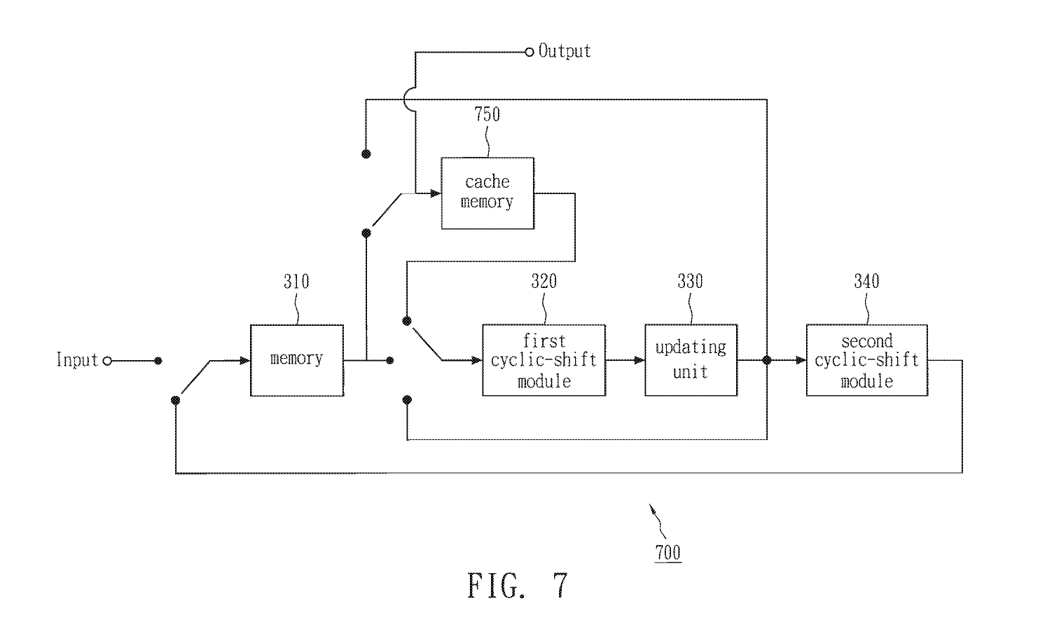

FIG. 7 shows a circuit for decoding LDPC code according to another embodiment of the present invention. The decoding circuit 700 is similar to the decoding circuit 300 shown in FIG. 3 with an additional cache memory 750, wherein the cache memory 750 can switch to receive either the output data of the memory 310 or the output data of the updating unit 330. The hard decision output terminal can also switch to receive either the output data of the memory 310 or the output data of the updating unit 330, and can be implemented by a switch. The memory 310 can switch to receive either an input data to be decoded with soft information or the output data of the second cyclic-shift module 340. The first cyclic-shift module 320 can switch to receive either the output data of the memory 310, the output data of the updating unit 330 or the output data of the cache memory 750. As shown in FIG. 7, the cache memory 750 can store the updated decoding data to avoid such read-after-write hazards.

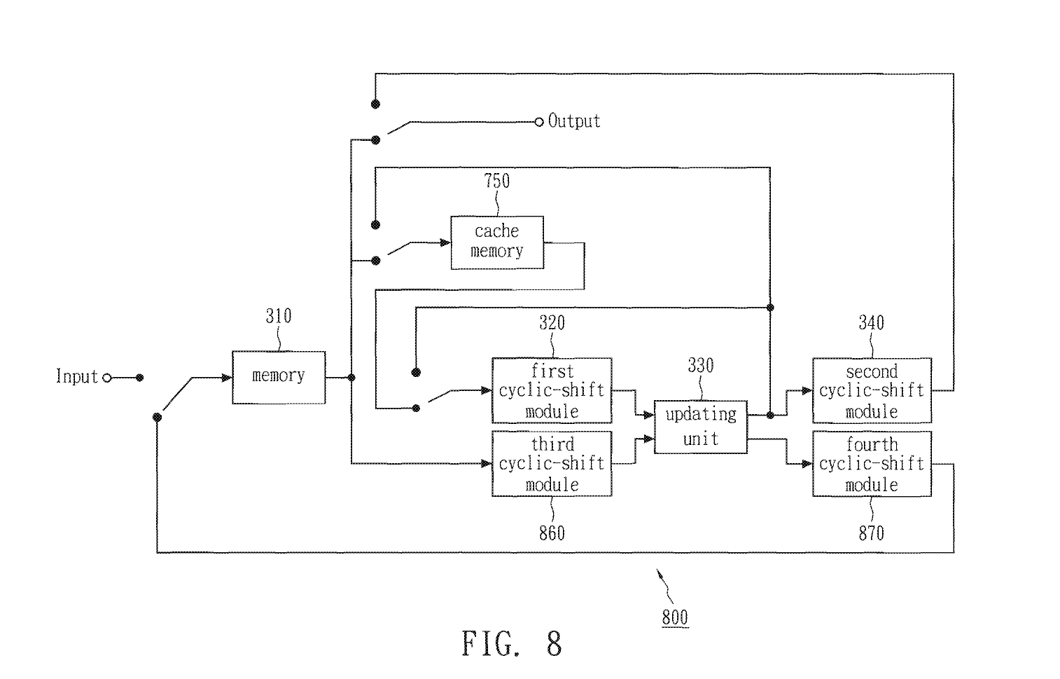

FIG. 8 shows a circuit for decoding LDPC code according to yet another embodiment of the present invention. The decoding circuit 800 is similar to the decoding circuit 700 shown in FIG. 7 with an additional third cyclic-shift module 860 and another additional fourth cyclic-shift module 870, wherein the cyclic-shift modules can be implemented by barrel shifters. The third cyclic-shift module 860 is configured to cyclic shift the output data of the memory 310 and output the result to the updating unit 330. The fourth cyclic-shift module 870 is configured to cyclic shift the output data of the updating unit 330. The cache memory 750 can switch to receive either the output data of the memory 310 or the output data of the updating unit 330. The hard decision output terminal can also switch to receive either the output data of the memory 310 or the output data of the second cyclic-shift module 340, and can be implemented by a switch. The first cyclic-shift module 320 can switch to receive either the output data of the updating unit 330 or the output data of the cache memory 750. The memory 310 can switch to receive either an input data to be decoded with soft information or the output data of the fourth cyclic-shift module 870. As shown in FIG. 8, the decoding path of the decoding circuit 800 can be divided as the path by which the decoding data are stored directly into the memory 310 and the path by which the memory 310 is bypassed and the cache memory 750 is utilized to proceed the subsequent decoding process such that the flexibility of the decoding procedure is increased.

In conclusion, the method and circuit for decoding LDPC code according to the embodiments of the present invention can significantly decrease the access rate of memory, which not only improves the decoding success rate, but also reduces the power consumption and alleviates the circuit design burden.

The above-described embodiments of the present invention are intended to be illustrative only. Those skilled in the art may devise numerous alternative embodiments without departing from the scope of the following claims.

What is claimed is:

1. A method for decoding low density parity check (LDPC) code, comprising the steps of:
marking non-zero sub matrixes as 1 and zero sub matrixes as 0 in a parity check matrix of an LDPC code to generate a simplified matrix;
reordering rows of the simplified matrix according to a correlation of the rows; and
updating decoding data according to a sequence of the rows.

2. The method of claim 1, wherein the non-zero sub matrixes are identity matrixes or cyclic-shifted identity matrixes.

3. The method of claim 1, wherein the reordering step comprises the steps of:
representing the rows in numerals; and
reordering the rows in accordance with correlation of the numerals.

4. The method of claim 3, wherein the rows are reordered in accordance with magnitudes of the numerals.

5. The method of claim 1, wherein the updating step is determined according to a correlation between a row on which the decoding data is situated and immediately upper and lower rows thereof.

6. The method of claim 5, wherein if an entry corresponding to the decoding data to be updated is immediately adjacent to upper and lower entries with decoding data to be updated, then the decoding data are updated lastly and are stored firstly after being updated.

7. The method of claim 6, wherein a read sequence of the decoding data is opposite to a write sequence of the decoding data.

8. The method of claim 1, which is utilized in a wireless communication device complying with IEEE 802.11n standard.

9. A circuit for decoding low density parity check (LDPC) code, comprising:
a memory configured to store decoding data of an LPDC code;
a first cyclic-shift module;
an updating unit configured to update an output data of the first cyclic-shift module; and
a second cyclic-shift module configured to cyclic shift an output data of the updating unit;
wherein the first cyclic-shift module is operated reversely to the second cyclic-shift module, the memory receives either an input data to be decoded or an output data of the second cyclic-shift module, and the first cyclic-shift module receives either an output data of the memory or the output data of the updating unit.

10. The circuit of claim 9, wherein the cyclic-shift modules are implemented by barrel shifters.

11. The circuit of claim 9, wherein an output terminal of the memory is coupled to a hard decision output terminal.

12. The circuit of claim 9, which further comprises:
a cache memory configured to receive and store either the output data of the memory or the output data of the updating unit;
wherein the memory receives an input data to be decoded, the output data of the second cyclic-shift module or an output data of the cache memory.

13. The circuit of claim 12, which further comprises:
a switch configured to switch between the output data of the memory or the output data of the updating unit to a hard decision output terminal.

14. The circuit of claim 9, which is utilized in a wireless communication device complying with IEEE 802.11n standard.

15. A circuit for decoding low density parity check (LDPC) code, comprising:
a memory configured to store decoding data of an LPDC code;
a first cyclic-shift module;
a third cyclic-shift module configured to cyclic shift an output data of the memory;
an updating unit configured to update output data of the first cyclic-shift module and the third cyclic-shift module;
a second cyclic-shift module configured to cyclic shift an output data of the updating unit;
a fourth cyclic-shift module configured to cyclic shift the output data of the updating unit; and
a cache memory configured to receive and store either the output data of the memory or the output data of the updating unit;
wherein the first cyclic-shift module is operated reversely to the second cyclic-shift module, the third cyclic-shift module is operated reversely to the fourth cyclic-shift module, the memory receives either an input data to be decoded or an output data of the fourth cyclic-shift module, and the first cyclic-shift module receives either the output data of the updating unit or an output data of the cache memory.

16. The circuit of claim 15, wherein the cyclic-shift modules are implemented by barrel shifters.

17. The circuit of claim 15, which further comprises:
a switch configured to switch between the output data of the memory or the output data of the first cyclic-shift module to a hard decision output terminal.

18. The circuit of claim 15, which is utilized in a wireless communication device complying with IEEE 802.11n standard.
